(19) United States
(12) Patent Application Publication
(10) Pub. No.: US 2023/0304149 A1
(43) Pub. Date: Sep. 28, 2023

(54) SUBSTRATE PROCESSING APPARATUS, METHOD OF MANUFACTURING SEMICONDUCTOR DEVICE AND SUBSTRATE SUPPORT

(71) Applicant: Kokusai Electric Corporation, Tokyo (JP)

(72) Inventors: Kenichi SUZAKI, Toyama-shi (JP); Yuma Ikeda, Toyama-shi (JP)

(73) Assignee: Kokusai Electric Corporation, Tokyo (JP)

(21) Appl. No.: 18/184,320

(22) Filed: Mar. 15, 2023

(30) Foreign Application Priority Data
Mar. 25, 2022 (JP) 2022-049853

(51) Int. Cl. C23C 16/44; C23C 16/458; C23C 16/46

(52) U.S. Cl. CPC C23C 16/4405; C23C 16/4584; C23C 16/46; H01L 21/02178

(57) ABSTRACT

According to the present disclosure, there is provided a technique for improving the deposit removal efficiency and reducing particle generation. According to one aspect thereof, there is provided a substrate processing apparatus including: a substrate support column; a heat insulator below a substrate support region; and a process vessel accommodating the substrate support column and the heat insulator. The heat insulator includes a side wall portion of a cylindrical shape facing an inner wall of the process vessel; and an upper end portion facing the substrate support region for closing an upper end of the side wall portion. At least a part of the upper end portion facing the substrate support region is constituted by an upper surface portion made of a first material whose thermal conductivity is higher than that of a second material constituting the upper end of the side wall portion and the substrate support column.

### CROSS-REFERENCE TO RELATED PATENT APPLICATION

This non-provisional U.S. patent application is based on and claims priority under 35 U.S.C. § 119 of Japanese Patent Application No. 2022-049853 filed on Mar. 25, 2022, in the Japanese Patent Office, the entire contents of which are hereby incorporated by reference.

### BACKGROUND

### 1. Field

The present disclosure relates to a substrate processing apparatus, a method of manufacturing a semiconductor device and a substrate support.

### 2. Related Art

According to some related arts, as a part of a manufacturing process of a semiconductor device, a cleaning step may be performed. According to the cleaning step, by supplying an etching gas into a process chamber where a substrate is processed, it is possible to remove a substance such as deposits attached to an inner surface of the process chamber.

However, when the deposits are not sufficiently removed by the etching gas supplied in the cleaning step, the deposits (which are not removed by the cleaning step) may become particles or the like. Thereby, a processing of the substrate may be affected.

### SUMMARY

According to the present disclosure, there is provided a technique capable of improving a removal efficiency of deposits when removing the deposits by using an etching gas and capable of reducing a generation of particles and the like caused by a residue of the deposits.

According to an aspect of the technique of the present disclosure, there is provided a substrate processing apparatus including: a substrate support column capable of supporting a plurality of substrates; a heat insulator provided below a substrate support region of the substrate support column; and a process vessel in which the substrate support column and the heat insulator are accommodated, wherein the heat insulator comprises: a side wall portion of a cylindrical shape facing an inner wall of the process vessel; and an upper end portion facing the substrate support region and capable of closing an upper end of the side wall portion, and wherein at least a part of a surface of the upper end portion facing the substrate support region is constituted by an upper surface portion made of a first material whose thermal conductivity is higher than that of a second material constituting the upper end of the side wall portion and the substrate support column.

### BRIEF DESCRIPTION OF THE DRAWINGS

FIG. 1 is a diagram schematically illustrating a vertical cross-section of a vertical type process furnace of a substrate processing apparatus according to one or more embodiments of the present disclosure.

FIG. 2 is a diagram schematically illustrating a horizontal cross-section, taken along a line A-A shown in FIG. 1, of the vertical type process furnace of the substrate processing apparatus according to the embodiments of the present disclosure.

FIG. 3 is a diagram schematically illustrating a substrate support according to the embodiments of the present disclosure.

FIG. 4 is a diagram schematically illustrating a cross-section of an example of a heat insulator of the substrate support according to the embodiments of the present disclosure.

FIG. 5 is a diagram schematically illustrating a cross-section of another example of the heat insulator of the substrate support according to the embodiments of the present disclosure.

FIG. 6 is a block diagram schematically illustrating a configuration of a controller and related components of the substrate processing apparatus according to the embodiments of the present disclosure.

FIG. 7 is a flow chart schematically illustrating an exemplary flow of a method of manufacturing a semiconductor device according to the embodiments of the present disclosure.

### DETAILED DESCRIPTION

### Embodiments of Present Disclosure

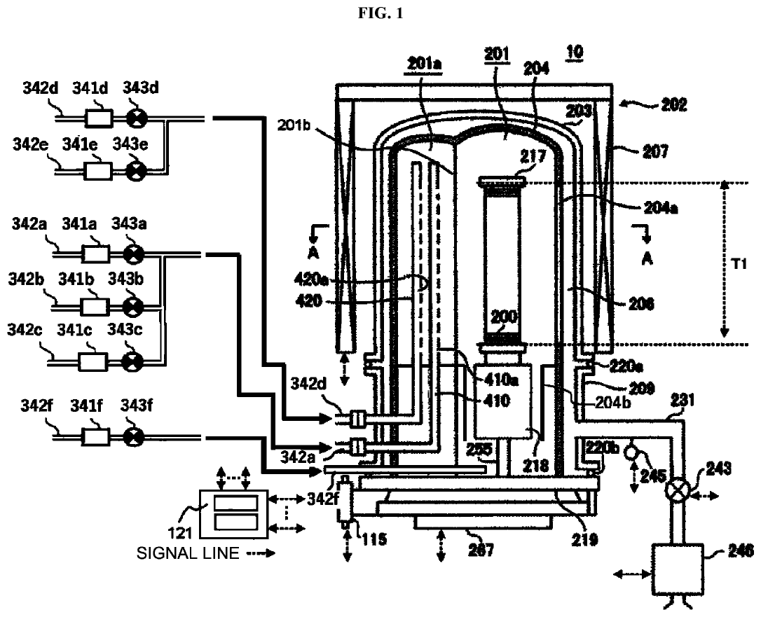

Hereinafter, one or more embodiments (also simply referred to as “embodiments”) of the technique of the present disclosure will be described in detail with reference to FIGS. 1 through 7. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

(1) Configuration of Substrate Processing Apparatus

As shown in FIG. 1, a substrate processing apparatus 10 according to the present embodiments includes a process furnace 202. The process furnace 202 includes a heater 207 serving as a heating structure (which is a heating apparatus or a heating system). The heater 207 is of a cylindrical shape, and is vertically installed while being supported by a support plate (not shown). The heater 207 also functions as an activator (also referred to as an “exciter”) capable of activating (or exciting) a gas by a heat. The heater 207 is provided at a position facing a substrate support region 402 described later and outside of a heat insulator (which is a heat insulating structure) 218 described later. That is, according to the present embodiments, the heater 207 is not provided inside the heat insulator 218.

A reaction tube constituting a reaction vessel (which is a process vessel) is provided in an inner side of the heater 207 to be aligned in a manner concentric with the heater 207. For example, the reaction tube is embodied by a double tube configuration including an inner tube (also referred to as an “inner cylinder” or an “inner tube structure”) 204 and an outer tube (also referred to as an “outer cylinder” or an “outer tube structure”) 203 provided to surround the inner tube 204 and to be aligned in a manner concentric with the inner tube 204. For example, each of the inner tube 204 and the outer tube 203 is made of a heat resistant material such as quartz (SiO₂) and silicon carbide (SiC). For example, each of the inner tube 204 and the outer tube 203 is of a cylindrical shape with a closed upper end and an open lower end.

A process chamber 201 in which a plurality of wafers including a wafer 200 serving as a substrate are processed is provided in a hollow cylindrical portion of the inner tube 204 (that is, an inner region of the reaction vessel). Hereinafter, the plurality of wafers including the wafer 200 may also simply be referred to as wafers 200. The process chamber 201 is configured such that the wafers 200 can be accommodated in the process chamber 201 while being arranged in the process chamber 201 from an end (that is, a lower end) toward the other end (that is, an upper end) of the process chamber 201. An inner portion of the process chamber 201 may be divided into a plurality of regions. According to the present embodiments, a region in the process chamber 201 in which the wafers 200 are arranged in the process chamber 201 may also be referred to as the “substrate support region 402” or a “wafer support region 402”. The substrate support region 402 may also be referred to as a “substrate arrangement region” or a “wafer arrangement region”. The substrate support region 402 includes a region in which a temperature thereof is maintained uniform by the heater 207 (that is, a soaking region Ti) in order to process the wafers 200 uniformly. In the process chamber 201, a region including the substrate support region 402 and surrounded by the heater 207, that is, a region whose temperature is relatively high may also be referred to as a “high temperature region”. Further, in the process chamber 201, a region without including the substrate support region 402 and without being substantially surrounded by the heater 207 (that is, a region around the heat insulator 218 described later), that is, a region whose temperature is relatively low may also be referred to as a “low temperature region”. Specifically, the low temperature region is a region in the process chamber 201 below an upper surface of the heat insulator 218. In addition, a direction in which the wafers 200 are arranged in the process chamber 201 may also be referred to as a “substrate arrangement direction” or a “wafer arrangement direction”.

A manifold (which is an inlet flange) 209 is provided under the outer tube 203 to be aligned in a manner concentric with the outer tube 203. Each of the inner tube 204 and the outer tube 203 is supported by the manifold 209 from thereunder. For example, the manifold 209 is made of a metal material such as stainless steel (SUS). The manifold 209 is of a cylindrical shape with open upper and lower ends. The lower end of the outer tube 203 is in contact with the upper end of the manifold 209. As shown in FIG. 1, an O-ring 220a serving as a seal is provided between the manifold 209 and the outer tube 203. As the manifold 209 is supported by a heater base (not shown) (that is, the support plate described above), the outer tube 203 is installed vertically. The reaction vessel is constituted mainly by the outer tube 203, the inner tube 204 and the manifold 209.

An auxiliary chamber (which is a nozzle accommodating chamber) 201a is provided in the hollow cylindrical portion of the inner tube 204. The auxiliary chamber 201a is of a channel shape (a groove shape) protruding outward in a radial direction of the inner tube 204 from a side wall of the inner tube 204 and extending (stretching) along a vertical direction. An inner wall of the auxiliary chamber 201a constitutes a part of an inner wall of the process chamber 201. When viewed from above, it can be said that the auxiliary chamber 201a and the process chamber 201 communicate with each other through an opening 201b provided in the inner tube 204.

A cover 204b is provided along an inner wall of each of the inner tube 204 and the auxiliary chamber 201a so as to protrude from the inner wall of each of the inner tube 204 and the auxiliary chamber 201a toward a central axis of the inner tube 204. The cover 204b serves as a gas flow path restrictor (which is a gas flow path restricting structure) capable of limiting (or restricting) a flow path of a gas such as a source gas and a reactive gas. For example, the cover 204b can be made of a material such as quartz and silicon carbide. The cover 204b is provided in a range facing at least a part of a side surface (that is, a side wall portion 404) of the heat insulator 218. That is, when viewed from above, the cover 204b is provided so as to surround an outer periphery of the heat insulator 218. By forming a flow path (through which an inert gas supplied via a gas supply pipe 342f described later flows upward from below) between the cover 204b and the side surface of the heat insulator 218, the cover 204b is capable of preventing (or suppressing) the source gas or the reactive gas supplied to the substrate support region 402 from coming into contact with the side surface or a lower portion of the heat insulator 218. As a result, it is possible to suppress a formation of deposits on the side surface, the lower portion or an inner portion of the heat insulator 218. Further, according to the present embodiments, for example, the gas flow path restrictor is implemented by the cover 204b. However, the present embodiments are not limited thereto. For example, the gas flow path restrictor may be implemented by a structure of a block shape, or a structure in which a portion of the inner tube 204 protrudes inward.

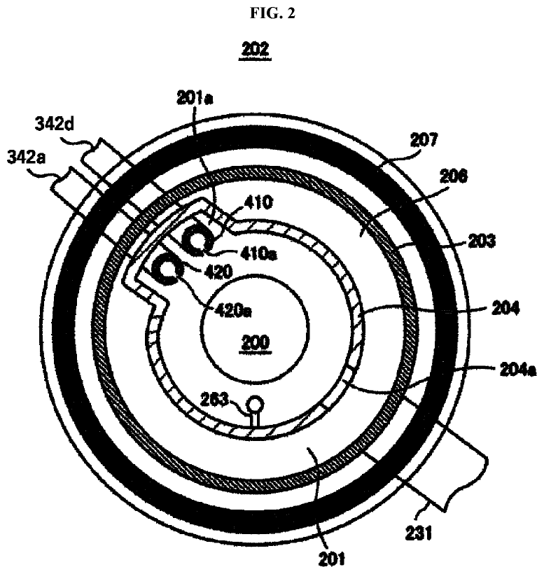

Nozzles 410 and 420 serving as a part of a gas supplier (which is a gas supply structure or a gas supply system) described later are accommodated in the auxiliary chamber 201a. For example, each of the nozzles 410 and 420 is made of a heat resistant material such as quartz and silicon carbide. Each of the nozzles 410 and 420 may be configured as an L-shaped long nozzle. Horizontal portions of the nozzles 410 and 420 are installed so as to penetrate a side wall of the manifold 209. Vertical portions of the nozzles 410 and 420 are installed in the auxiliary chamber 201a so as to extend upward from a lower portion toward an upper portion of the inner wall of the auxiliary chamber 201a along the wafer arrangement direction. That is, as shown in FIG. 2, the nozzles 410 and 420 are installed in a region that horizontally surrounds the substrate support region 402 on a peripheral area of the substrate support region 402 to extend along the substrate support region 402. As shown in FIG. 1, the nozzles 410 and 420 are provided such that upper ends of the nozzles 410 and 420 are located near a ceiling of a boat 217 described later. In the present disclosure, the nozzles 410 and 420 may also be referred to as a “first nozzle” and a “second nozzle”, respectively.

A plurality of gas supply holes (which are openings) 410a and a plurality of gas supply holes (which are openings) 420a are provided at side surfaces of the nozzles 410 and 420, respectively. Gases such as the source gas and the reactive gas are supplied through the gas supply holes 410a and the gas supply holes 420a, respectively. The gas supply holes 410a of the nozzle 410 and the gas supply holes 420a of the nozzle 420 are provided from upper portions to lower portions of the nozzles 410 and 420, respectively, along the wafer arrangement direction at positions facing the wafers 200, that is, in a manner corresponding to an entire area of the substrate support region 402. That is, the gas supply holes 410a and the gas supply holes 420a are provided at positions from a lower portion to an upper portion of the boat 217 described later such that the gases can be ejected to each of the wafers 200 accommodated in the boat 217 through the gas supply holes 410a and the gas supply holes 420a, respectively.

According to the present embodiments, the gases such as the source gas and the reactive gas are supplied through the nozzles 410 and 420 provided in the auxiliary chamber 201a which forms a cylindrical space, respectively. Then, the gases are ejected into the process chamber 201 through the gas supply holes 410a and the gas supply holes 420a opened in the nozzles 410 and 420, respectively. The gases ejected into the inner tube 204 mainly flow parallel to surfaces of the wafers 200, that is, in a horizontal direction. Thereby, it is possible to uniformly supply the gas to each of the wafers 200. After passing the surfaces of the wafers 200, the gas flows toward an exhaust hole 204a described later, However, a flow direction of the gas may vary depending on a location of the exhaust hole 204a, and is not limited to the horizontal direction.

Gas supply pipes 342a and 342d are connected to the nozzles 410 and 420, respectively. As described above, the two nozzles 410 and 420 and the two gas supply pipes 342a and 342d are connected to the inner tube 204, and thereby it is possible to supply various gases into the process chamber 201 through the two nozzles 410 and 420 and the two gas supply pipes 342a and 342d.

The gas supply pipe 342f is connected to a lower portion of the manifold 209. The gas supply pipe 342f is provided so as to penetrate lower side walls of the manifold 209 and the inner tube 204.

Gas supply pipes 342b and 342c are connected to the gas supply pipe 342a so as to be conjoined with one another, and a gas supply pipe 342e is connected to the gas supply pipe 342d so as to be conjoined with each other. Mass flow controllers (MFCs) 341a, 341b, 341c, 341d, 341e and 341f serving as flow rate controllers (flow rate control structures) and valves 343a, 343b, 343c, 343d, 343e and 343f serving as opening/closing valves are sequentially installed at the gas supply pipes 342a, 342b, 342c, 342d, 342e and 342f in this order from upstream sides to downstream sides of the gas supply pipes 342a, 342b, 342c, 342d, 342e and 342f, respectively, in a gas flow direction.

As the source gas serving as one of process gases, a gas containing a predetermined element serving as a primary element (main element) constituting a film formed on the wafer 200 (that is, a predetermined element-containing gas) can be supplied into a wafer processing region (that is, the substrate support region 402) in the process chamber 201 through the gas supply pipe 342a. In the present specification, the term “source gas” may refer to a source material in a gaseous state such as a gas obtained by vaporizing the source material in a liquid state under the normal temperature and the normal pressure, or may refer to a source material in a gaseous state under the normal temperature and the normal pressure. The predetermined element-containing gas acts as a film-forming gas, that is, a predetermined element source material.

An etching gas serving as a cleaning gas used in a cleaning process described later can be supplied into the process chamber 201 through the gas supply pipe 342b.

The reactive gas (reactant) serving as one of the process gases can be supplied into the wafer processing region in the process chamber 201 through the gas supply pipe 342d. For example, an oxidizing gas or a nitriding gas may be used as the reactive gas. The reactive gas acts as the film-forming gas.

The inert gas can be supplied into the wafer processing region in the process chamber 201 through the gas supply pipes 342c and 342e. The inert gas acts as a purge gas, a dilution gas or a carrier gas.

The inert gas can be further supplied into the low temperature region in the process chamber 201 through the gas supply pipe 342f. The inert gas supplied through the gas supply pipe 342f acts as the purge gas. For example, the inert gas supplied through the gas supply pipe 342f is supplied between the inner wall of the process chamber 201 and the side wall portion 404. The inert gas supplied through the gas supply pipe 342f is also supplied to at least one among an outer peripheral space or an inner space 404B of the heat insulator 218. Further, an inert gas supplier (which is an inert gas supply structure or an inert gas supply system) constituted by components such as a nozzle and capable of purging the side wall portion 404 of the heat insulator 218 and an inert gas supplier constituted by components such as a nozzle and capable of purging the inner space 404B may be integrated as a single body, or may be provided separately. In addition, the gas supply pipe 342f may be connected to a rotator (which is a rotating structure) 267 described later so as to supply the inert gas from an outer periphery of a rotating shaft 255 to the low temperature region in the process chamber 201.

A source gas supplier (which is a source gas supply structure, a source gas supply system or a metal-containing source gas supplier) is constituted mainly by the gas supply pipe 342a, the MFC 341a and the valve 343a. The source gas supplier may further include the nozzle 410. A reactive gas supplier (which is a reactive gas supply structure, a reactive gas supply system or an oxygen-containing gas supplier) is constituted mainly by the gas supply pipe 342d, the MFC 341d and the valve 343d. The reactive gas supplier may further include the nozzle 420. The source gas supplier and the reactive gas supplier may be collectively referred to as a process gas supplier (which is a process gas supply structure, a process gas supply system, a gas supplier, a gas supply structure or a gas supply system). Further, at least one among the source gas supplier or the reactive gas supplier may be referred to as the process gas supplier. A first inert gas supplier (which is a first inert gas supply structure, a first inert gas supply system, a purge gas supplier, a dilution gas supplier or a carrier gas supplier) is constituted mainly by the gas supply pipes 342c and 342e, the MFCs 341c and 341e and the valves 343c and 343e. A second inert gas supplier (which is a second inert gas supply structure, a second inert gas supply system or a purge gas supplier) is constituted mainly by the gas supply pipe 342f, the MFC 341f and the valve 343f. An etching gas supplier (which is an etching gas supply structure, an etching gas supply system, a cleaning gas supply structure or a cleaning gas supply system) is constituted mainly by the gas supply pipe 342b, the MFC 341b and the valve 343b.

As shown in FIG. 1, the exhaust hole (exhaust slit) 204a is provided on the side wall of the inner tube 204. For example, the exhaust hole 204a may be of a narrow slit-shaped through-hole elongating vertically. For example, the exhaust hole 204a is of a rectangular shape when viewed from front. The exhaust hole 204a is provided so as to cover the entirety of the wafer arrangement region along the wafer arrangement direction from a lower portion to an upper portion of the side wall of the inner tube 204. The exhaust hole 204a is not limited to the slit-shaped through-hole. For example, the exhaust hole 204a may be configured as a plurality of holes. An inside of the process chamber 201 and an exhaust path 206 defined by an annular space (gap) between the inner tube 204 and the outer tube 203 are in communication with each other through the exhaust hole 204a.

As shown in FIG. 2, when viewed from above, the auxiliary chamber 201a and the exhaust hole 204a are provided so as to face each other with a center of the wafer 200 accommodated in the process chamber 201 interposed therebetween (that is, the exhaust hole 204a is provided at a location opposite to the auxiliary chamber 201a by 180°). Further, the nozzles 410 and 420 and the exhaust hole 204a are provided so as to face each other with the center of the wafer 200 accommodated in the process chamber 201 interposed therebetween.

As shown in FIG. 1, an exhaust pipe 231 through which an inner atmosphere of the process chamber 201 is exhausted is connected to the manifold 209 through the exhaust path 206. A vacuum pump 246 serving as a vacuum exhaust apparatus is connected to the exhaust pipe 231 through a pressure sensor 245 serving as a pressure detector (pressure detecting structure) configured to detect an inner pressure of the exhaust path 206 (that is, an inner pressure of the process chamber 201) and an APC (Automatic Pressure Controller) valve 243 serving as a pressure regulator (which is a pressure adjusting structure). With the vacuum pump 246 in operation, the APC valve 243 may be opened or closed to perform a vacuum exhaust of the process chamber 201 or stop the vacuum exhaust. With the vacuum pump 246 in operation, an opening degree of the APC valve 243 may be adjusted in order to adjust the inner pressure of the process chamber 201 based on pressure information detected by the pressure sensor 245. An exhauster (which is an exhaust structure or an exhaust system), that is, an exhaust line is constituted mainly by the exhaust pipe 231, the APC valve 243 and the pressure sensor 245. The exhauster may further include the exhaust hole 204a, the exhaust path 206 and the vacuum pump 246.

A lower end opening of the manifold 209 is configured as a furnace opening of the process furnace 202. When the boat 217 is elevated by a boat elevator 115 described later, the lower end opening of the manifold 209 is airtightly (hermetically) sealed by a seal cap 219 serving as a lid through an O-ring 220b. For example, the seal cap 219 is made of a metal such as SUS, and is of a disk shape. The rotator 267 configured to rotate the boat 217 is provided below the seal cap 219. The rotating shaft 255 of the rotator 267 is connected to the boat 217 through the seal cap 219. As the rotator 267 rotates the boat 217, the wafers 200 accommodated in the boat 217 are rotated. The seal cap 219 may be elevated or lowered in the vertical direction by the boat elevator 115 serving as an elevating structure vertically provided outside the outer tube 203. When the seal cap 219 is elevated or lowered in the vertical direction by the boat elevator 115, the wafers 200 accommodated in the boat 217 may be transferred (loaded) into the process chamber 201 or transferred (unloaded) out of the process chamber 201. The boat elevator 115 serves as a transfer device (which is a transfer structure) capable of loading the boat 217 and the wafers 200 supported by the boat 217 into the process chamber 201 and capable of unloading the boat 217 and the wafers 200 supported by the boat 217 out of the process chamber 201.

The boat 217 serving as a substrate support (which is a substrate retainer) is configured to support (or accommodate) the wafers 200 while the wafers 200 are horizontally oriented with their centers aligned with one another in a multistage manner. The boat 217 may include: a plurality of substrate support columns including a substrate support column 400 capable of supporting the wafers 200; and the heat insulator 218 provided below the substrate support region 402 of the substrate support columns 400. Hereinafter, the plurality of substrate support columns including the substrate support column 400 may also be referred to as substrate support columns 400. The inner tube 204 is configured to be capable of accommodating the boat 217 including the substrate support columns 400 and the heat insulator 218.

The heat insulator 218 may include: the side wall portion 404 of a cylindrical shape facing the inner wall of the process chamber 201; and an upper end portion 406 facing the substrate support region 402 and capable of closing an upper end of the side wall portion 404. Further, at least a part of a surface of the upper end portion 406 facing the substrate support region 402 is configured as an upper surface portion 408 made of a first material whose thermal conductivity is higher than that of a second material constituting the upper end of the side wall portion 404 or the substrate support columns 400.

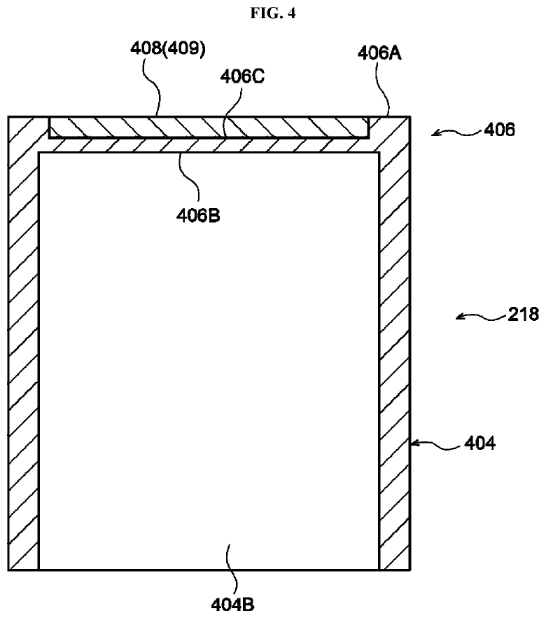

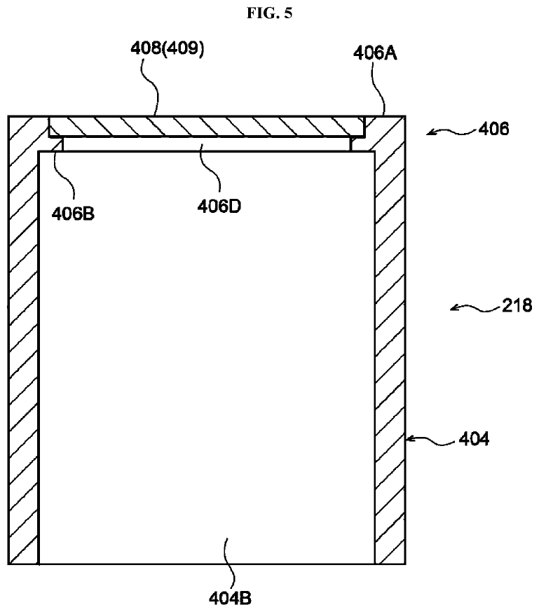

The upper surface portion 408 may be provided so as to include at least a center of the upper end portion 406. In such a case, the “center” may also be rephrased as a “central point”. Further, an outer edge (outer periphery) 406A of the upper end portion 406 may be made of the second material. The upper surface portion 408 may be configured as a plate-shaped structure 409 made of the first material. In examples shown in FIGS. 4 and 5, the plate-shaped structure 409 is of a disk shape. For example, the first material includes silicon carbide (SiC), and the second material includes quartz (SiO₂).

The plate-shaped structure 409 may be detachably provided on a support structure 406B provided on the upper end portion 406. Specifically, the support structure 406B may be provided with a recess (which is a concave portion) 406C, and the plate-shaped structure 409 may be fitted into the recess 406C. The support structure 406B may be made of the second material.

As shown in FIG. 5, the plate-shaped structure 409 may be provided such that a lower surface thereof faces (or is exposed to) the inner space 404B of the heat insulator 218. In such a case, a through-hole 406D is provided in the support structure 406B while leaving the remaining portion of the support structure 406B in a flange shape, and the plate-shaped structure 409 is supported by the remaining portion of the support structure 406B. As a result, a bottom surface of the plate-shaped structure 409 faces the inner space 404B of the heat insulator 218.

It is preferable that the heat insulator 218 is of a hollow structure surrounded by the side wall portion 404 and the upper end portion 406 (that is, a structure in which components such as a heat insulating plate and the heater are not provided). The heat insulating plate (not shown) is not supported inside the heat insulator 218. However, one or more heat insulating plates may be supported inside the heat insulator 218.

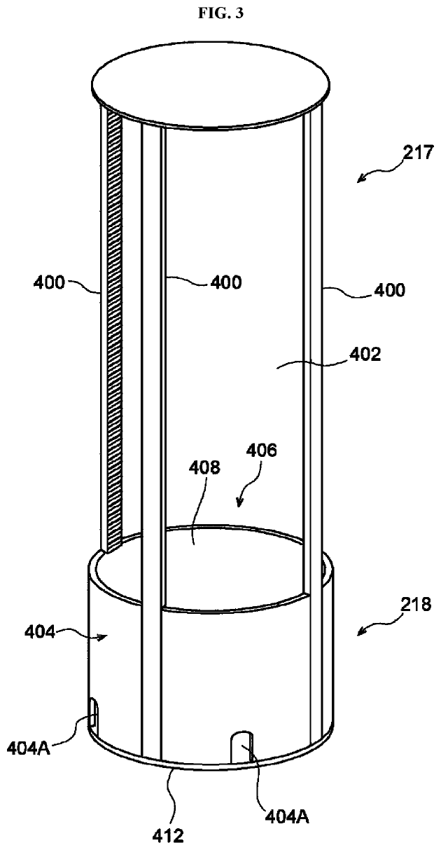

The side wall portion 404 may be provided with a plurality of openings including an opening 404A through which an outer space of the heat insulator 218 communicates with the inner space 404B of the heat insulator 218. Hereinafter, the plurality of openings including the opening 404A may also be referred to as openings 404A. As shown in FIG. 3, for example, the openings 404A are provided at a lower end portion of the side wall portion 404. Further, the openings 404A are provided at a plurality of locations in a circumferential direction of the side wall portion 404, respectively.

The substrate support columns 400 are configured to be capable of supporting the wafers 200 while the wafers 200 are horizontally oriented and spaced apart from one another. As shown in FIG. 3, the substrate support columns 400 may be vertically installed on a base plate 412 serving as a base structure located at a lowermost portion of the heat insulator 218. Alternatively, for example, the substrate support columns 400 may be vertically installed on the outer edge 406A of the upper end portion 406. In other words, the substrate support columns 400 are provided near the upper surface portion 408 in a non-contact manner.

A temperature sensor 263 serving as a temperature detector is installed in the inner tube 204.

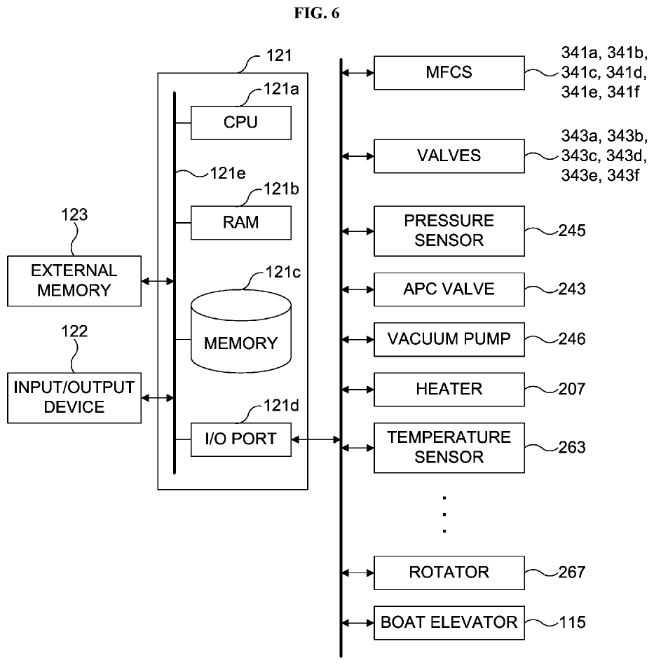

As shown in FIG. 6, a controller 121 serving as a control device (control structure) is constituted by a computer including a CPU (Central Processing Unit) 121a, a RAM (Random Access Memory) 121b, a memory 121c and an I/O port 121d. The RAM 121b, the memory 121c and the I/O port 121d may exchange data with the CPU 121a through an internal bus 121e. For example, an input/output device 122 constituted by components such as a touch panel is connected to the controller 121.

The memory 121c is configured by a component such as a flash memory and a hard disk drive (HDD). For example, at least one among a temperature control program configured to control a temperature of a liquid source material, a control program configured to control operations of the substrate processing apparatus 10 or a process recipe containing information on process sequences and process conditions of a method of manufacturing a semiconductor device (that is, a substrate processing) described later may be readably stored in the memory 121c. The process recipe is obtained by combining steps of the method of manufacturing the semiconductor device described later such that the controller 121 constituted by the computer can execute the steps by using the substrate processing apparatus 10 to acquire a predetermined result, and functions as a program. Hereafter, the process recipe and the control program (and the temperature control program) described above may be collectively or individually referred to as a “program”. Thus, in the present specification, the term “program” may refer to the process recipe alone, may refer to at least one among the control program or the temperature control program, or may refer to a combination of the process recipe and at least one among the control program or the temperature control program. The RAM 121b functions as a memory area (work area) where a program or data read by the CPU 121a is temporarily stored.

The I/O port 121d is connected to the at least one of components described above such as the MFCs 341a, 341b, 341c, 341d, 341e and 341f, the valves 343a, 343b, 343c, 343d, 343e and 343f, the pressure sensor 245, the APC valve 243, the vacuum pump 246, the heater 207, the temperature sensor 263, the rotator 267 and the boat elevator 115.

The CPU 121a is configured to read the control program from the memory 121c and execute the read control program. In addition, the CPU 121a is configured to read a recipe such as the process recipe from the memory 121c in accordance with an operation command inputted from the input/output device 122. According to the contents of the read recipe, the CPU 121a may be configured to be capable of controlling various operations such as flow rate adjusting operations for various gases by the MFCs 341a, 341b, 341c, 341d, 341e and 341f, opening and closing operations of the valves 343a, 343b, 343c, 343d, 343e and 343f, an opening and closing operation of the APC valve 243, a pressure adjusting operation by the APC valve 243 based on the pressure sensor 245, a temperature adjusting operation by the heater 207 based on the temperature sensor 263, a start and stop of the vacuum pump 246, an operation of adjusting a rotation and a rotation speed of the boat 217 by the rotator 267, an elevating and lowering operation of the boat 217 by the boat elevator 115 and an operation of transferring and accommodating the wafer 200 into the boat 217.

The controller 121 may be embodied by installing the above-described program stored in an external memory 123 into the computer. For example, the external memory 123 may include a magnetic tape, a magnetic disk such as a flexible disk and a hard disk, an optical disk such as a CD and a DVD, a magneto-optical disk such as an MO and a semiconductor memory such as a USB memory and a memory card. The memory 121c or the external memory 123 may be embodied by a non-transitory computer readable recording medium. Hereafter, the memory 121c and the external memory 123 may be collectively or individually referred to as a “recording medium”. Thus, in the present specification, the term “recording medium” may refer to the memory 121c alone, may refer to the external memory 123 alone, and may refer to both of the memory 121c and the external memory 123. Instead of the external memory 123, a communication structure such as the Internet and a dedicated line may be used for providing the program to the computer.

The controller 121 is configured to be capable of controlling the process gas supplier and the etching gas supplier so as to perform: (A) a film-forming process of forming a film on the wafer (substrate) 200 accommodated in the process chamber 201 by supplying the film-forming gas into the process chamber 201 (that is, into process vessel); and (B) a cleaning process of removing the film deposited in the process chamber 201 by supplying the etching gas into the process chamber 201.

(2) Substrate Processing

Hereinafter, as a part of a manufacturing process of the semiconductor device according to the present embodiments, an example of the method of manufacturing the semiconductor device of forming the film on the wafer 200 will be described. The method of manufacturing the semiconductor device is performed by using the substrate processing apparatus 10 described above. In the following description, operations of components constituting the substrate processing apparatus 10 are controlled by the controller 121.

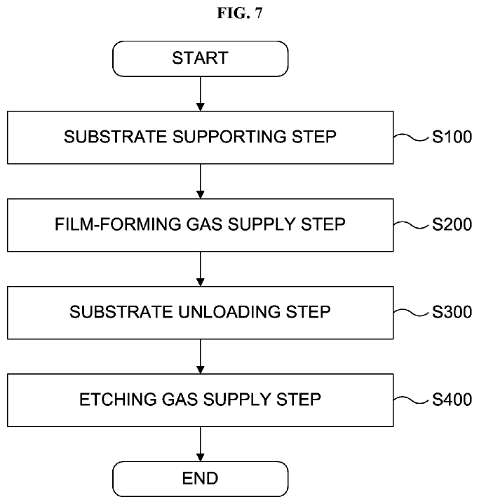

FIG. 7 is a flow chart schematically illustrating an exemplary flow of the method of manufacturing the semiconductor device according to the present embodiments. Referring to FIG. 7, the method of manufacturing the semiconductor device may include: (a) supporting the wafer 200 in the boat (which is the substrate support) 217 (S100 shown in FIG. 7); (b) supplying the film-forming gas into the process chamber 201 in which the boat 217 with the wafer 200 supported therein is accommodated (S200 shown in FIG. 7); (c) unloading (or discharging) the wafer 200 from the boat 217 (S300 shown in FIG. 7); and (d) supplying the etching gas into the process chamber 201 in which the boat 217 without the wafer 200 supported therein is accommodated (S400 shown in FIG. 7).

In the present specification, the term “wafer” may refer to “a wafer itself”, or may refer to “a wafer and a stacked structure (aggregated structure) of a predetermined layer (or layers) or a film (or films) formed on a surface of the wafer”. That is, the term “wafer” may collectively refer to the wafer and the layers or the films formed on the surface of the wafer. In the present specification, the term “a surface of a wafer” may refer to “a surface (exposed surface) of a wafer itself”, or may refer to “a surface of a predetermined layer or a film formed on a wafer, i.e. a top surface (uppermost surface) of the wafer as a stacked structure”. In the present specification, the terms “substrate” and “wafer” may be used as substantially the same meaning. That is, the term “substrate” may be substituted by “wafer” and vice versa.

(A) Film-Forming Process

The film-forming process will be described by way of an example in which a film containing a predetermined element is formed on the wafer 200 by supplying the film-forming gas onto the wafer 200 by using the substrate processing apparatus 10. According to the present embodiments, the process chamber 201 accommodating the boat 217 with the wafer 200 supported therein is heated to a predetermined temperature. Then, a source gas supply step of supplying the source gas containing the predetermined element (which serves as the film-forming gas) into the process chamber 201 and a reactive gas supply step of supplying the reactive gas (which also serves as the film-forming gas) into the process chamber 201 are performed a predetermined number of times (n times).

<Wafer Charging Step and Boat Loading Step>

The wafers 200 are loaded into the process chamber 201. Specifically, when the wafers 200 are charged into the boat 217 (wafer charging step), as shown in FIG. 2, the boat 217 charged with the wafers 200 is elevated by the boat elevator 115 and loaded (transferred) into the process chamber 201 (boat loading step). With the boat 217 loaded, the seal cap 219 seals the lower end opening of the manifold 209 via the O-ring 220b.

<Pressure Adjusting Step and Temperature Adjusting Step>

The vacuum pump 246 vacuum-exhausts the inner atmosphere of the process chamber 201 such that the inner pressure of the process chamber 201 reaches and is maintained at a desired pressure (vacuum degree). Meanwhile, the inner pressure of the process chamber 201 is measured by the pressure sensor 245, and the APC valve 243 is feedback-controlled based on the pressure information detected by the pressure sensor 245 (pressure adjusting step). The vacuum pump 246 continuously vacuum-exhausts the inner atmosphere of the process chamber 201 until at least a processing of the wafer 200 is completed. Further, the heater 207 heats the process chamber 201 such that the inner temperature of the process chamber 201 reaches and is maintained at a desired temperature. Meanwhile, an amount of the electric current supplied to the heater 207 is feedback-controlled based on temperature information detected by the temperature sensor 263 such that a desired temperature distribution of the inner temperature of the process chamber 201 is obtained (temperature adjusting step). The heater 207 continuously heats the process chamber 201 until at least the processing of the wafer 200 is completed.

In addition, the rotator 267 rotates the boat 217 and the wafers 200 accommodated in the boat 217. The rotator 267 continuously rotates the boat 217 and the wafers 200 until at least the processing of the wafer 200 is completed.

<Film-Forming Step>

Thereafter, a film-forming step is performed by performing a cycle a predetermined number of times, the cycle including the source gas supply step (also referred to as a first gas supply step), a first residual gas removing step, the reactive gas supply step (also referred to as a second gas supply step) and a second residual gas removing step. In the cycle, for example, the source gas supply step, the first residual gas removing step, the reactive gas supply step and the second residual gas removing step are sequentially performed in this order.

<Source Gas Supply Step>

The valve 343a is opened to supply the source gas into the gas supply pipe 342a. After a flow rate of the source gas is adjusted by the MFC 341a, the source gas whose flow rate is adjusted is supplied into the process chamber 201. Simultaneously with a supply of the source gas, the valve 343c is opened to supply the carrier gas serving as the inert gas into the gas supply pipe 342a. After a flow rate of the carrier gas is adjusted by the MFC 341c, the carrier gas whose flow rate is adjusted is supplied together with the source gas into the process chamber 201, and is exhausted through the exhaust pipe 231. Further, in order to prevent the source gas from entering the gas supply pipe 342d (that is, in order to prevent the source gas from flowing back to the gas supply pipe 342d), the valve 343e may be opened to supply the carrier gas into the gas supply pipe 342d. In addition, in order to prevent the source gas from coming into contact with the side wall portion 404 of the heat insulator 218 and/or the inner space 404B of the heat insulator 218, the valve 343f may be opened to supply the inert gas serving as the purge gas to the furnace opening of the process chamber 201 through the gas supply pipe 342f.

In the source gas supply step, for example, the APC valve 243 is appropriately adjusted such that the inner pressure of the process chamber 201 is set to be a predetermined pressure within a range from 1 Pa to 1,000 Pa, preferably from 1 Pa to 100 Pa, and more preferably from 10 Pa to 50 Pa. Further, in the present specification, a notation of a numerical range such as “from 1 Pa to 1,000 Pa” means that a lower limit and an upper limit are included in the numerical range. Therefore, for example, a numerical range “from 1 Pa to 1,000 Pa” means a range equal to or higher than 1 Pa and equal to or lower than 1,000 Pa. The same also applies to other numerical ranges described herein.

For example, a supply flow rate of the source gas controlled (or adjusted) by the MFC 341a is set to be a predetermined flow rate within a range from 10 sccm to 2,000 sccm, preferably from 50 sccm to 1,000 sccm, and more preferably from 100 sccm to 500 sccm.

For example, a supply flow rate of the carrier gas controlled (or adjusted) by the MFC 341c is set to be a predetermined flow rate within a range from 1 slm to 30 slm. For example, a supply time (time duration) of supplying the source gas onto the wafer 200 is set to be a predetermined time within a range from 1 second to 60 seconds, preferably from 1 second to 20 seconds, and more preferably from 2 seconds to 15 seconds. In the source gas supply step, for example, nitrogen (N₂) gas or a rare gas such as argon (Ar) gas, helium (He) gas, neon (Ne) gas and xenon (Xe) gas may be used as the inert gas serving as the carrier gas. For example, one or more of the gases described above may also be used as the inert gas. The same also applies to other inert gases described later.

For example, the heater 207 heats the process chamber 201 such that a temperature of the wafer 200 is set to be a predetermined temperature within a range from 200° C. to 600° C., preferably from 350° C. to 550° C., and more preferably from 400° C. to 550° C.

For example, as the source gas, a metal-containing gas containing aluminum (Al) as a metal element serving as the predetermined element, that is, an aluminum-containing source gas may be used. The aluminum-containing source gas may also be referred to as an “aluminum-containing source material” or an “aluminum-containing gas”. For example, as the aluminum-containing source gas, a halogen-based aluminum-containing gas such as aluminum chloride (AlCl₃) gas or an organic-based aluminum-containing gas such as trimethylaluminum (Al(CH₃)₃, abbreviated as TMA) gas may be used.

By supplying the source gas into the process chamber 201 in accordance with the process conditions described above, a first layer is formed on an uppermost surface of the wafer 200. For example, when the aluminum-containing gas is used as the source gas, an aluminum-containing layer is formed as the first layer. The aluminum-containing layer may be an adsorption layer (a physical adsorption layer or a chemical adsorption layer) of the aluminum-containing gas or substances generated by decomposing a part of the aluminum-containing gas, or may be an aluminum deposition layer (an aluminum layer).

<First Residual Gas Removing Step>

Then, the valve 343a is closed to stop the supply of the source gas. With the APC valve 243 open, the vacuum pump 246 vacuum-exhausts the inner atmosphere of the process chamber 201 to remove a residual gas such as the source gas which did not react or which did contribute to a formation of the first layer from the process chamber 201. By maintaining the valves 343c, 343e and 343f open, the carrier gas is continuously supplied into the process chamber 201.

<Reactive Gas Supply Step>

After the residual gas in the process chamber 201 is removed from the process chamber 201, the valve 343d is opened to supply the reactive gas into the gas supply pipe 342d. After a flow rate of the reactive gas is adjusted by the MFC 341d, the reactive gas whose flow rate is adjusted is supplied to the wafer 200 in the process chamber 201 through the gas supply pipe 342d, and is exhausted through the exhaust pipe 231. That is, the wafer 200 is exposed to the reactive gas.

In the reactive gas supply step, simultaneously with a supply of the reactive gas, the valve 343e is opened to supply the carrier gas into the gas supply pipe 342e. After the flow rate of the carrier gas is adjusted by the MFC 341e, the carrier gas whose flow rate is adjusted is supplied with the reactive gas into the process chamber 201, and is exhausted through the exhaust pipe 231. In the reactive gas supply step, in order to prevent the reactive gas from entering the gas supply pipe 342a (that is, in order to prevent the reactive gas from flowing back to the gas supply pipe 342a), the valve 343c is opened to supply the carrier gas into the gas supply pipe 342a. Furthermore, similar to the source gas supply step, in order to prevent the reactive gas from coming into contact with the side wall portion 404 of the heat insulator 218 and/or the inner space 404B of the heat insulator 218, the valve 343f may be opened to supply the inert gas serving as the purge gas to the furnace opening of the process chamber 201 through the gas supply pipe 342f. However, a flow rate (supply flow rate) of the purge gas supplied through the gas supply pipe 342f in the reactive gas supply step may be smaller than that of the purge gas supplied through the gas supply pipe 342f in the source gas supply step, or a supply of the purge gas through the gas supply pipe 342f may be stopped in the reactive gas supply step.

In the reactive gas supply step, for example, the APC valve 243 is appropriately adjusted such that the inner pressure of the process chamber 201 is set to be a predetermined pressure within a range from 1 Pa to 1,000 Pa. For example, a supply flow rate of the reactive gas controlled (or adjusted) by the MFC 341d is set to be a predetermined flow rate within a range from 5 slm to 40 slm, preferably from 5 slm to 30 slm, and more preferably from 10 slm to 20 slm. For example, a supply time (time duration) of supplying the reactive gas onto the wafer 200 is set to be a predetermined time within a range from 1 second to 60 seconds. Other process conditions of the reactive gas supply step are substantially the same as those of the source gas supply step described above.

For example, a gas reacting with the source gas such as an oxidizing gas may be used as the reactive gas. For example, an oxygen-containing gas such as oxygen (O₂) gas, ozone (O₃) gas, plasma-excited O₂ gas (O₂* gas), a mixed gas of the O₂ gas and hydrogen (H₂) gas, water vapor (H₂O gas), hydrogen peroxide (H₂O₂) gas, nitrous oxide (N₂O) gas, nitrogen monoxide (NO) gas, nitrogen dioxide (NO₂) gas, carbon monoxide (CO) gas and carbon dioxide (CO₂) gas may be used as the oxidizing gas. One or more of the gases described above may be used as the oxidizing gas.

In the reactive gas supply step, the reactive gas and the inert gas are supplied into the process chamber 201 without any other gas being supplied into the process chamber 201 together with the reactive gas and the inert gas. The reactive gas reacts with at least a portion of the first layer formed on the wafer 200 in the source gas supply step. That is, in a case where the aluminum-containing gas is used as the source gas and the aluminum-containing layer is formed as the first layer in the source gas supply step, the aluminum-containing layer serving as the first layer is oxidized to form an aluminum oxide layer (also referred to as an “AlO layer”) containing aluminum (Al) and oxygen (O) and serving as a metal oxide layer (which is a second layer). That is, the aluminum-containing layer is modified into the aluminum oxide layer.

<Second Residual Gas Removing Step>

Thereafter, the valve 343d is closed to stop the supply of the reactive gas. In the second residual gas removing step, a residual gas such as the reactive gas in the process chamber 201 which did not react or which did contribute to a formation of the second layer and reaction by-products are removed from the process chamber 201 in the same manners as in the first residual gas removing step performed after the source gas supply step.

<Performing Predetermined Number of Times>

By performing the cycle wherein the source gas supply step, the first residual gas removing step, the reactive gas supply step and the second residual gas removing step described above are sequentially performed in this order a predetermined number of times (one or more times), that is, by performing a batch process (in which the steps are performed a plurality of times), the film is formed on the wafer 200. Thereby, for example, an aluminum oxide film (also referred to as an “AlO film”) serving as a film containing aluminum (Al) and oxygen (O) is formed on the wafer 200.

In the film-forming process described above, a film (deposits) may adhere (or may be deposited) on locations such as a surface of the upper surface portion 408 of the heat insulator 218 and the inner wall of the process chamber 201 (for example, the inner wall of the inner tube 204 and the inner wall of the manifold 209 may be included) with which the source gas and the reactive gas come into contact. Due to the film adhered to the inside of the process chamber 201 as described above, particles (foreign matter) may be generated in a subsequent film-forming process. As a result, a quality of the film or a device (that is, the semiconductor device) formed on the wafer 200 may deteriorate. Therefore, in the method of manufacturing the semiconductor device according to the present embodiments, the film adhered to a location such as the inside of the process chamber 201 is removed in the cleaning process described later. For example, the deposits adhered to the inside of the process chamber 201 and the like may contain not only the film whose composition is substantially the same as the film formed on the wafer 200 but also the by-products generated in the film-forming process. In addition, the deposits may contain a substance such as quartz fallen off an inner surface of the inner tube 204. According to the present embodiments, by providing the cover 204b, it is possible to suppress an adhesion of the deposits to a surface of the side wall portion 404 of the heat insulator 218. Thereby, by removing the deposits adhered to a portion facing the substrate support region 402 in the cleaning process described later, it is possible to efficiently suppress a generation of the particles and the like caused by the deposits.

In the present specification, the term “batch process” refers to a process of forming the film on the wafer 200 by performing the cycle wherein the source gas supply step, the first residual gas removing step, the reactive gas supply step and the second residual gas removing step described above are sequentially performed in this order the predetermined number of times. By performing each batch process, the film is formed on the wafer 200.

<After-Purge Step and Returning to Atmospheric Pressure Step>

The inert gas is supplied into the process chamber 201 through each of the gas supply pipes 342a, 342d and 342f, and then is exhausted through the exhaust pipe 231. The inert gas serves as the purge gas, and the inner atmosphere of the process chamber 201 is purged with the inert gas. Thereby, a residual gas in the process chamber 201 and the reaction by-products remaining in the process chamber 201 are removed from the process chamber 201 (after-purge step). Thereafter, the inner atmosphere of the process chamber 201 is replaced with the inert gas (substitution by inert gas), and the inner pressure of the process chamber 201 is returned to the normal pressure (atmospheric pressure) (returning to atmospheric pressure step).

<Boat Unloading Step and Wafer Discharging Step>

Thereafter, the seal cap 219 is lowered by the boat elevator 115 and the lower end opening of the manifold 209 is opened. The boat 217 with the processed wafers 200 charged therein is unloaded out of the inner tube 204 through the lower end opening of the manifold 209 (boat unloading step). Then, the processed wafers 200 are discharged (transferred) from the boat 217 (wafer discharging step). The wafer discharging step (and the boat unloading step) may also be referred to as a “substrate unloading step”.

(B) Cleaning Process

Subsequently, the cleaning process of etching (or removing) the film adhered to the location such as the inside of the process chamber 201 in the film-forming process will be described.

<Boat Accommodating Step (Boat Loading Step)>

After the boat 217 is unloaded out of the process chamber 201 and the wafers 200 are discharged (transferred) from the boat 217, the boat 217 without accommodating the wafers 200 (also referred to as an “empty boat 217”) is loaded back into the process chamber 201. With the empty boat 217 loaded, the seal cap 219 seals the lower end opening of the manifold 209 via the O-ring 220b.

<Pressure Adjusting Step and Temperature Adjusting Step>

The vacuum pump 246 vacuum-exhausts the inner atmosphere of the process chamber 201 such that the inner pressure of the process chamber 201 reaches and is maintained at a desired pressure (vacuum degree). Meanwhile, the inner pressure of the process chamber 201 is measured by the pressure sensor 245, and the APC valve 243 is feedback-controlled based on the pressure information detected by the pressure sensor 245 (pressure adjusting step). The vacuum pump 246 continuously vacuum-exhausts the inner atmosphere of the process chamber 201 until at least an etching process described later is completed. Further, the heater 207 heats the process chamber 201 such that the inner temperature of the process chamber 201 reaches and is maintained at a desired temperature. Meanwhile, the amount of the electric current supplied to the heater 207 is feedback-controlled based on the temperature information detected by the temperature sensor 263 such that a desired temperature distribution of the inner temperature of the process chamber 201 is obtained (temperature adjusting step). The heater 207 continuously heats the process chamber 201 until at least the etching process is completed.

<Etching Process (Cleaning Step)>

Then, an etching process of etching the film adhered to the location such as the inside of the process chamber 201 so as to clean the inside of the process chamber 201 is performed by performing a cycle including an etching step and a third residual gas removing step a plurality number of times.

<Etching Step>

The valve 343b is opened to supply the etching gas serving as the cleaning gas into the gas supply pipe 342a through the gas supply pipe 342b. After a flow rate of the etching gas is adjusted by the MFC 341b, the etching gas whose flow rate is adjusted is supplied into the process chamber 201 through the gas supply pipe 342b, the gas supply pipe 342a and the nozzle 410, and is exhausted through the exhaust pipe 231. Simultaneously with a supply of the etching gas, the valve 343c is opened to supply the inert gas into the gas supply pipe 342a through the gas supply pipe 342c. After a flow rate of the inert gas supplied through the gas supply pipe 342c is adjusted by the MFC 341c, the inert gas whose flow rate is adjusted and serving as a dilution gas (carrier gas) is supplied with the etching gas into the process chamber 201, and is exhausted through the exhaust pipe 231. Further, in the etching step, in order to prevent the etching gas from entering the gas supply pipes 342d and 342f, the valves 343e and 343f may be opened to supply the inert gas into the gas supply pipes 342d and 342f.

For example, a halogen-containing gas such as boron trichloride (BCl₃) gas, silicon tetrachloride (SiCl₄) gas, hydrogen chloride (HCl) gas, chlorine (Cl₂) gas, fluorine (F₂) gas, hydrogen fluoride (HF) gas, silicon tetrafluoride (SiF₄) gas, nitrogen trifluoride (NF₃) gas, chlorine trifluoride (ClF₃) gas, boron tribromide (BBr₃) gas, silicon tetrabromide (SiBr₄) gas and bromine (Br₂) gas may be used as the etching gas. One or more of the gases described above may be used as the etching gas.

By supplying the etching gas, the deposits adhered to the location such as the inside of the process chamber 201 (particularly, the deposits adhered to the inner wall of the inner tube 204 facing the substrate support region 402, adhered to the substrate support columns 400 of the boat 217 or adhered to the surface of the upper surface portion 408) react with the etching gas and thereby are removed from the process chamber 201. For example, when the SiCl₄ gas is used as the etching gas, at least a portion of the aluminum oxide film adhered to the inside of the process chamber 201 reacts with the etching gas (SiCl₄ gas), and thereby is removed from the process chamber 201.

In the etching step, for example, the heater 207 is appropriately controlled (or adjusted) by the controller 121 to heat the inside of the process chamber 201 to a predetermined temperature within a range from 200° C. to 800° C., preferably from 400° C. to 650° C. such that the etching gas is activated. According to the present embodiments, the upper surface portion 408 of the heat insulator 218 is configured as the plate-shaped structure 409 made of the first material whose thermal conductivity is high. Thereby, it is possible to uniformly heat the upper surface portion 408 on the surface of the upper surface portion 408. As a result, it is possible to efficiently and uniformly remove the deposits adhered to the surface of the upper surface portion 408. In the etching step, for example, the APC valve 243 may be closed or substantially closed to an extent that the etching step is not affected. Thereby, the etching gas is filled in the process chamber 201. By filling the etching gas in the process chamber 201, it is possible to reduce an influence of a reaction delay on the etching step. In the etching step, for example, the inner pressure of the process chamber 201 is set to be a predetermined pressure (that is, a first pressure) within a range from 1 Pa to 40,000 Pa, preferably from 10,000 Pa to 30,000 Pa, and more preferably from 20,000 Pa to 30,000 Pa. For example, a supply flow rate of the etching gas controlled (or adjusted) by the MFC 341b is set to be a predetermined flow rate within a range from 1 slm to 10 slm, preferably from 3 slm to 8 slm. For example, a supply time (time duration) of supplying of the etching gas into the process chamber 201 is set to be a predetermined time within a range from 60 seconds to 600 seconds.

<Third Residual Gas Removing Step>

After the etching gas is supplied into the process chamber 201 for a predetermined time, the valve 343b is closed to stop the supply of the etching gas. If the APC valve 243 is closed or substantially closed to the extent that the etching step is not affected, the process proceeds to open the APC valve 243. In the third residual gas removing step, a residual gas such as the etching gas in the process chamber 201 which did not react or which did contribute to a removal of the film (that is, the deposits) is removed from the process chamber 201 in the same manners as in the first residual gas removing step performed after the source gas supply step.

<Performing Predetermined Number of Times>

By performing the cycle wherein the etching step and the third residual gas removing step are sequentially performed in this order one or more times (a predetermined number of times (m times)), the film (that is, the deposits) adhered to the inside of the process chamber 201 is removed. It is preferable that the cycle described above is repeatedly performed a plurality of times.

(3) Effects According to Present Embodiments

According to the present embodiments, by constituting at least a part of the upper surface of the heat insulator 218 with the first material whose thermal conductivity is higher than that of the second material constituting the other parts of the heat insulator 218, it is possible to suppress at least one among a heat leakage to the upper end of the side wall portion 404 of the heat insulator 218, a temperature decrease (temperature drop) of the upper surface of the heat insulator 218 or a non-uniformity of a temperature of the upper surface of the heat insulator 218. As a result, when removing the deposits (film) by using the etching gas, it is possible to improve a removal efficiency of the deposits (deposited film) deposited on the upper surface of the heat insulator 218, and it is also possible to reduce the particles of a powder shape resulting from a residue of the deposits (deposited film) deposited on the upper surface of the heat insulator 218.

By purging the surface of the side wall portion 404 with the inert gas in the film-forming process, it is possible to suppress a deposition of the deposits (film) on the side wall portion 404. Thereby, the upper end portion 406 of the heat insulator 218 alone can be selectively identified as a cleaning target region where the deposition of the deposits (deposited film) substantially occurs. Therefore, although a portion of high thermal conductivity exists only in the upper end portion 406 as in the present embodiments, it is possible to sufficiently obtain an effect of reducing the particles and the like.

By supplying the inert gas from a lower end to the upper end of the side wall portion 404 in the film-forming process, it is possible to prevent (or suppress) the film-forming gas from flowing into a space between the inner wall of the process chamber 201 and the side wall portion 404.

In a case where the upper surface portion 408 is provided so as to include at least the center of the upper end portion 406, it is possible to suppress the temperature decrease on a surface in the vicinity of the center of the upper end portion 406 where the temperature decrease is most likely to occur.

In a case where the outer edge 406A of the upper end portion 406 is made of the second material, it is possible to suppress an occurrence of the temperature decrease on the upper surface portion 408 and an occurrence of the non-uniformity of the temperature of the upper surface portion 408 due to the heat leakage to the side wall portion 404 via the outer edge 406A.

In a case where the plate-shaped structure 409 is provided such that the lower surface thereof faces the inner space 404B of the heat insulator 218, by reducing an area of contact (that is, a contact surface) between the support structure 406B made of the second material and a lower surface of the upper surface portion 408 to reduce the heat leakage through the contact surface, it is possible to further suppress the occurrence of the temperature decrease on the upper surface portion 408 and the occurrence of the non-uniformity of the temperature of the upper surface portion 408.

As described above, the first material may be silicon carbide (SiC) and the second material may be quartz (SiO). For example, when the BCl₃ gas is used as the etching gas for etching the aluminum oxide film serving as the deposited film as in the present embodiments, it is preferable to select silicon carbide as the first material because it is difficult to etch SiC with the BCl₃ gas. Further, instead of silicon carbide, another material such as silicon (Si) and aluminum oxide (AlO) whose thermal conductivity is higher than that of quartz may be used as the first material. However, the first material is not limited to those described above. That is, depending on the type of etching gas used for the removal of the deposits (film), a material which would not be etched (or easily etched) by such type of the etching gas can be preferably used as the first material.

In a case where the heat insulator 218 is of the hollow structure surrounded by the side wall portion 404 and the upper end portion 406, it is possible to easily and efficiently purge the inner space 404B of the heat insulator 218. However, in such a case, since there is no heater or heat insulating material inside the heat insulator 218, the heat leakage due to a heat radiation from the upper surface of the heat insulator 218 to the inner space 404B of the heat insulator 218 is likely to occur. However, according to the technique of the present disclosure, it is possible to suppress the temperature decrease on the upper surface of the heat insulator 218 and the non-uniformity of the temperature of the upper surface of the heat insulator 218 which are caused by the heat leakage due to the hollow structure of the heat insulator 218.

In a case where the side wall portion 404 is provided with the openings 404A through which the outer space of the heat insulator 218 communicates with the inner space 404B of the heat insulator 218 and the inert gas is supplied through the gas supply pipe 342f to the outer peripheral space of the heat insulator 218 in the film-forming process, the inert gas flows into the inner pace 404B through the openings 404A provided in the side wall portion 404 of the heat insulator 218. Thereby, it is possible to purge the inner pace 404B of the heat insulator 218 with the inert gas. In addition, in a case where the inert gas is directly supplied to the inner pace 404B of the heat insulator 218 in the film-forming process (for example, when the nozzle through which the inert gas is supplied is provided within the inner space 404B), it is also possible to purge the inner pace 404B with the inert gas. Therefore, it is possible to suppress the deposition of the deposits (deposited film) caused by the film-forming gas flowing into the inner space 404B. That is, it is possible to further suppress the generation of the particles and the like caused by the deposits (deposited film).

By providing the substrate support columns 400 near the upper surface portion 408 in a non-contact manner, it is possible to suppress the heat leakage from the upper surface portion 408 to the substrate support columns 400.

It is preferable that a coefficient of thermal expansion of the deposited film (which is deposited on the inner wall of the process chamber 201 and the upper surface portion 408 of the heat insulator 218 by supplying the film-forming gas into the process chamber 201) is closer to a coefficient of thermal expansion of the first material than to a coefficient of thermal expansion of the second material. In such a case, the deposits (deposited film) is less likely to crack on the upper surface portion 408. Thereby, in addition to suppressing the particles of a powder shape resulting from a crack of the deposits (deposited film), it is also possible to suppress a generation of particles (of a powder shape) of a material constituting the upper surface portion 408 due to a crack on the surface of the upper surface portion 408 caused by the crack of the deposits (deposited film).

### Program According to Present Embodiments

A program according to the present embodiments, that causes, by a computer, the substrate processing apparatus 10 to perform: (a) supporting the wafer 200 in the boat 217; (b) supplying the film-forming gas into the process chamber 201 in which the boat 217 with the wafer 200 supported therein is accommodated; (c) unloading (or discharging) the wafer 200 from the boat 217; and (d) supplying the etching gas into the process chamber 201 in which the boat 217 without the wafer 200 supported therein is accommodated. The program may be recorded in a storage medium.

### Other Embodiments of Present Disclosure

For example, the embodiments described above are described by way of an example in which the aluminum oxide film is formed on the wafer 200 and the aluminum oxide film deposited in the process furnace 202 is etched (or removed) by using the etching gas. However, the technique of the present disclosure is not limited thereto. For example, a type of the film is not particularly limited. Further, types of the gases such as the source gas and the reactive gas used in the film-forming process are not particularly limited.

It is preferable that the process recipe (that is, a program defining parameters such as the process sequences and the process conditions of the substrate processing (that is, the film-forming process) used to form various films according to the technique of the present disclosure is prepared individually in accordance with the contents of the substrate processing such as the type of the film to be formed, a composition ratio of the film, a quality of the film, a thickness of the film, the process sequences and the process conditions of the substrate processing. A cleaning recipe is preferably prepared individually in accordance with the contents of the cleaning process in the same manners. That is, a plurality of process recipes (and a plurality of cleaning recipes) are prepared. When starting the substrate processing (or the cleaning process), an appropriate process recipe is preferably selected among the process recipes in accordance with the contents of the substrate processing (or an appropriate cleaning recipe is preferably selected among the cleaning recipes in accordance with the contents of the cleaning process). Specifically, it is preferable that the process recipes (or the cleaning recipes) are stored (or installed) in the memory 121c of the substrate processing apparatus 10 in advance via an electric communication line or the recording medium (for example, the external memory 123) storing the process recipes prepared individually in accordance with the contents of the substrate processing (or the cleaning recipes prepared individually in accordance with the contents of the cleaning process). Then, when starting the substrate processing (or the cleaning process), the CPU 121a preferably selects the appropriate process recipe among the process recipes stored in the memory 121c of the substrate processing apparatus 10 in accordance with the contents of the substrate processing (or the CPU 121a preferably selects the appropriate cleaning recipe among the cleaning recipes stored in the memory 121c of the substrate processing apparatus 10 in accordance with the contents of the cleaning process). Thus, various films of different types, different composition ratios, different qualities and different thicknesses may be universally formed with a high reproducibility using a single substrate processing apparatus. In addition, since a burden on an operator such as inputting the process sequences and the process conditions may be reduced, various processes can be performed quickly while avoiding a malfunction of the substrate processing apparatus 10.

The technique of the present disclosure may also be implemented by changing an existing process recipe (or an existing cleaning recipe) stored in the substrate processing apparatus to a new process recipe (or a new cleaning recipe). When changing the existing process recipe to the new process recipe (or changing the existing cleaning recipe to the new cleaning recipe), the new process recipe (or the new cleaning recipe) may be installed in the substrate processing apparatus 10 via the electric communication line or the recording medium storing the process recipes (or the cleaning recipes). Alternatively, the existing process recipe (or the existing cleaning recipe) itself already stored in the substrate processing apparatus 10 may be directly changed to the new process recipe (or the new cleaning recipe) according to the technique of the present disclosure by operating the input/output device of the substrate processing apparatus 10.

While the technique is described in detail by way of the embodiments and the other embodiments (modified examples), the technique of the present disclosure is not limited thereto. The technique of the present disclosure may be modified in various ways without departing from the scope thereof.

According to some embodiments of the present disclosure, it is possible to provide the technique capable of improving the removal efficiency of the deposits when removing the deposits by using the etching gas and capable of reducing the generation of the particles and the like caused by the residue of the deposits.

What is claimed is:

1. A substrate processing apparatus comprising:
a substrate support column capable of supporting a plurality of substrates;
a heat insulator provided below a substrate support region of the substrate support column; and
a process vessel in which the substrate support column and the heat insulator are accommodated,
wherein the heat insulator comprises: a side wall portion of a cylindrical shape facing an inner wall of the process vessel; and an upper end portion facing the substrate support region and capable of closing an upper end of the side wall portion, and
wherein at least a part of a surface of the upper end portion facing the substrate support region is constituted by an upper surface portion made of a first material whose thermal conductivity is higher than that of a second material constituting the upper end of the side wall portion and the substrate support column.

2. The substrate processing apparatus of claim 1, wherein the substrate support column is configured to be capable of supporting the plurality of substrates while the plurality of substrates are horizontally oriented and spaced apart from one another.

3. The substrate processing apparatus of claim 1, further comprising
an inert gas supplier through which an inert gas is supplied between the inner wall of the process vessel and the side wall portion.

4. The substrate processing apparatus of claim 1, wherein the upper surface portion is provided so as to include at least a center of the upper end portion.

5. The substrate processing apparatus of claim 4, wherein an outer edge of the upper end portion is made of the second material.

6. The substrate processing apparatus of claim 1, wherein the upper surface portion is constituted by a plate-shaped structure made of the first material.

7. The substrate processing apparatus of claim 6, wherein the plate-shaped structure is detachably provided on a support structure provided on the upper end portion.

8. The substrate processing apparatus of claim 7, wherein the support structure is provided with a recess, and the plate-shaped structure is fitted into the recess.

9. The substrate processing apparatus of claim 7, wherein the support structure is made of the second material.

10. The substrate processing apparatus of claim 1, wherein the first material comprises silicon carbide, and the second material comprises quartz.

11. The substrate processing apparatus of claim 1, wherein the heat insulator is of a hollow structure surrounded by the side wall portion and the upper end portion.

12. The substrate processing apparatus of claim 11, wherein the side wall portion is provided with an opening through which an outer space of the heat insulator communicates with an inner space of the heat insulator.

13. The substrate processing apparatus of claim 1, further comprising
an inert gas supplier through which an inert gas is supplied to at least one of an outer space of the heat insulator or an inner space of the heat insulator.

14. The substrate processing apparatus of claim 11, further comprising
an inert gas supplier through which an inert gas is supplied to at least one of an outer space of the heat insulator or an inner space of the heat insulator.

15. The substrate processing apparatus of claim 1, wherein the substrate support column is vertically installed on a base structure located at a lowermost portion of the heat insulator.

16. The substrate processing apparatus of claim 1, further comprising
a heater provided at a position facing the substrate support region and outside of the heat insulator.

17. The substrate processing apparatus of claim 1, further comprising
a film-forming gas supplier through which a film-forming gas is supplied into the process vessel,
wherein a coefficient of thermal expansion of a film deposited on the inner wall of the process vessel and the upper surface portion by supplying the film-forming gas into the process vessel is closer to a coefficient of thermal expansion of the first material than to a coefficient of thermal expansion of the second material.

18. A method of manufacturing a semiconductor device, comprising:
(a) supporting a plurality of substrates in a substrate support, wherein the substrate support comprises:
a substrate support column capable of supporting the plurality of substrates; and
a heat insulator provided below a substrate support region of the substrate support column;
wherein the heat insulator comprises: a side wall portion of a cylindrical shape facing an inner wall of a process vessel; and an upper end portion facing the substrate support region and capable of closing an upper end of the side wall portion, and
wherein at least a part of a surface of the upper end portion facing the substrate support region is constituted by an upper surface portion made of a first material whose thermal conductivity is higher than that of a second material constituting the upper end of the side wall portion and the substrate support column;
(b) supplying a film-forming gas into the process vessel in which the substrate support with the plurality of substrates supported therein is accommodated;
(c) unloading the plurality of substrates from the substrate support; and
(d) supplying an etching gas into the process vessel in which the substrate support without the plurality of substrates supported therein is accommodated.

19. A substrate support comprising:
a substrate support column capable of supporting a plurality of substrates; and
a heat insulator provided below a substrate support region of the substrate support column;
wherein the heat insulator comprises: a side wall portion of a cylindrical shape facing an inner wall of a process vessel; and an upper end portion facing the substrate support region and capable of closing an upper end of the side wall portion, and
wherein at least a part of a surface of the upper end portion facing the substrate support region is constituted by an upper surface portion made of a first material whose thermal conductivity is higher than that of a second material constituting the upper end of the side wall portion and the substrate support column.
